(19) United States
(12) Patent Application Publication
(10) Pub. No.: US 2026/0163588 A1
(43) Pub. Date: Jun. 11, 2026

(54) STORAGE DEVICE AND METHOD OF OPERATING THE SAME

(71) Applicant: SAMSUNG ELECTRONICS CO., LTD., Suwon-si (KR)

(72) Inventors: Youngsik MOON, Suwon-si (KR); Sooyoung JI, Suwon-si (KR)

(73) Assignee: SAMSUNG ELECTRONICS CO., LTD., Suwon-si (KR)

(21) Appl. No.: 19/230,763

(22) Filed: Jun. 6, 2025

(30) Foreign Application Priority Data
Dec. 5, 2024 (KR) 10-2024-0179673

(51) Int. Cl. H03M 7/30; G06F 3/06

(52) U.S. Cl. CPC H03M 7/6064; G06F 3/0608; G06F 3/0643; G06F 3/0688

(57) ABSTRACT

A storage device includes a storage controller and a non-volatile memory. The storage controller includes an important data checker configured to check whether input data is important data, a semantic entropy checker configured to compare a semantic entropy of the input data with a first threshold value when the input data is deemed important, and a semantic compressor configured to, when a semantic entropy of the input data is less than or equal to the first threshold value, perform semantic compression on the input data, and store semantically compressed data in a first tier storage of the non-volatile memory.

### CROSS-REFERENCE TO RELATED APPLICATION

This application is based on and claims priority under 35 U.S.C. § 119 to Korean Patent Application No. 10-2024-0179673, filed on Dec. 5, 2024, in the Korean Intellectual Property Office, the disclosure of which is incorporated herein in its entirety by reference.

### BACKGROUND

The present disclosure relates to a storage device and a method of operating the same, and more particularly, to a layered storage device and a method of operating the same.

A flash memory is widely used as a non-volatile device with characteristics such as low power consumption and high integration. A representative example of a mass storage device based on flash memory is a solid state drive (SSD).

As demand for SSDs increases, SSDs for various purposes are being developed. SSDs store various types of data in various formats, and a memory hierarchy is presented to optimize data access according to purposes.

Meanwhile, data stored on SSDs may be in compressed form. Data compression in the prior art corresponds to compression that takes into account the mathematical characteristics of data, and, as the uses of SSDs diversify, research on a compression method exhibiting more efficiency and less loss than those in the prior art is needed.

### SUMMARY

The inventive concept provides a storage device capable of minimizing loss due to compression through semantic compression and a method of operating the same.

According to an aspect of the inventive concept, there is provided a storage device including a storage controller and a non-volatile memory, wherein the storage controller includes an important data checker configured to check whether input data is important data, a semantic entropy checker configured to compare a semantic entropy of the input data with a first threshold value when the input data is deemed important, and a semantic compressor configured to, when a semantic entropy of the input data is less than or equal to the first threshold value, perform semantic compression on the input data, and store semantically compressed data in a first tier storage of the non-volatile memory.

According to another aspect of the inventive concept, there is provided a storage device including a storage controller and a non-volatile memory, wherein the storage controller includes a semantic compressor and a non-semantic compressor, the non-volatile memory includes a first tier storage configured to store data of a first type, a second tier storage configured to store data of a second type, and a third tier storage configured to store data of a third type, and the data of the first type includes data semantically compressed by the semantic compressor, the data of the second type includes data non-semantically compressed by the non-semantic compressor, and the data of the third type includes uncompressed data.

According to another aspect of the inventive concept, there is provided a method of operating a storage device, the method including checking whether input data is important data, comparing a semantic entropy of the input data with a first threshold value when the input data is deemed important, performing semantic compression on the input data when the semantic entropy of the input data is less than or equal to the first threshold value, and storing semantically compressed data in a first tier storage of a non-volatile memory.

### BRIEF DESCRIPTION OF THE DRAWINGS

Embodiments of the present disclosure will be more clearly understood from the following detailed description taken in conjunction with the accompanying diagrams in which:

FIG. 1 is a block diagram showing a host-storage system according to an embodiment;

FIG. 2 is a block diagram illustrating a non-volatile memory of a storage device according to an embodiment;

FIG. 3 is a block diagram illustrating a compressor constituting a storage controller of a storage device according to an embodiment;

FIG. 4 is a flowchart of a method of operating a storage device, according to an embodiment;

FIG. 5 is a flowchart of a method of operating a storage device, according to an embodiment;

FIG. 6 is a flowchart of a method of operating a storage device, according to an embodiment;

FIG. 7 is a flowchart of a method of determining important data, according to an embodiment;

FIG. 8 is a flowchart of a method of determining important data, according to an embodiment;

FIG. 9 is a diagram showing a system to which a storage device according to an embodiment is applied; and

FIG. 10 is a block diagram showing a memory system according to an embodiment.

### DETAILED DESCRIPTION OF THE EMBODIMENTS

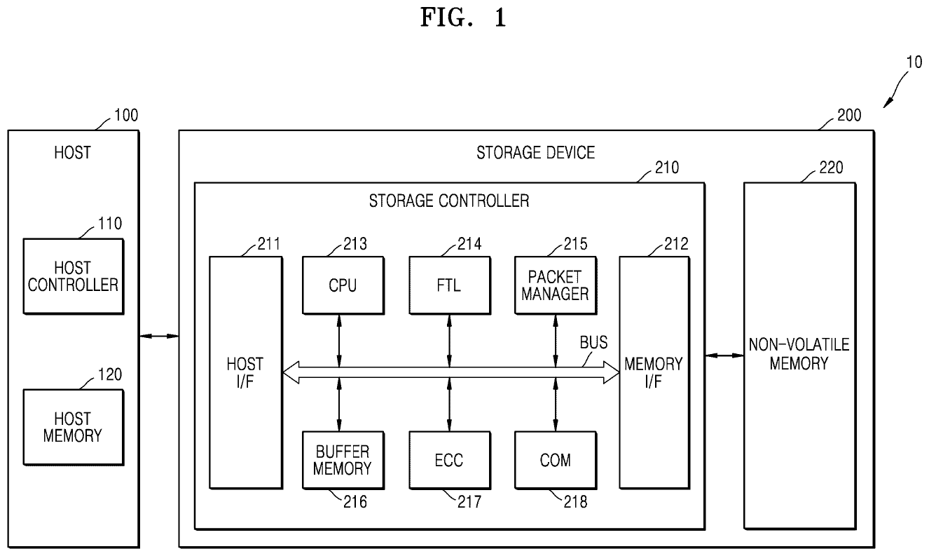

FIG. 1 is a block diagram showing a host-storage system according to an embodiment.

Referring to FIG. 1, a host-storage system 10 may include a host 100 and a storage device 200. Also, the storage device 200 may include a storage controller 210 and a non-volatile memory (NVM) 220. Also, the host 100 may include a host controller 110 and a host memory 120. The host memory 120 may function as a buffer memory for temporarily storing data to be transmitted to the storage device 200 or data transmitted from the storage device 200.

The storage device 200 may include storage media for storing data according to requests from the host 100. For example, the storage device 200 may include at least one of a solid state drive (SSD), an embedded memory, and a removable external memory. When the storage device 200 is an SSD, the storage device 200 may be a device complying with the non-volatile memory express (NVMe) standard. When the storage device 200 is an embedded memory or an external memory, the storage device 200 may be a device complying with the universal flash storage (UFS) standard or the embedded multi-media card (eMMC) standard. The host 100 and the storage device 200 may generate and transmit packets according to standard protocols employed thereby, respectively.

When the NVM 220 of the storage device 200 includes a flash memory, the flash memory may include a 2D NAND memory array or a 3D (or vertical) NAND (VNAND) memory array. In another example, the storage device 200 may include various other types of non-volatile memories. For example, the storage device 200 may include magnetic RAM (MRAM), spin-transfer torque MRAM, conductive bridging RAM (CBRAM), ferroelectric RAM (FeRAM), phase RAM (PRAM), resistive RAM, and various other types of memory.

The host controller 110 and the host memory 120 may be implemented as separate semiconductor chips. Alternatively, the host controller 110 and the host memory 120 may be integrated into the same semiconductor chip. According to an embodiment, the host controller 110 may be any one of a plurality of modules included in an application processor, and the application processor may be implemented as a system-on-chip (SoC). Also, the host memory 120 may be an embedded memory provided in the application processor or a non-volatile memory or a memory module disposed outside the application processor.

The host controller 110 may manage an operation of storing data (e.g., write data) of the buffer region of the host memory 120 in the NVM 220 or an operation of storing data (e.g., read data) of the NVM 220 in the buffer region of the host memory 120.

The storage controller 210 may include a host interface 211, a memory interface 212, and a central processing unit (CPU) 213. Also, the storage controller 210 may further include a flash translation layer (FTL) 214, a packet manager 215, a buffer memory 216, an error correction code (ECC) engine 217, and a compressor (COM) 218. The storage controller 210 may further include a working memory (not shown) in which the FTL 214 is loaded, and operations of programming and reading data to and from the NVM 220 may be controlled as the CPU 213 executes the FTL 214.

The host interface 211 may transmit and receive packets to and from the host 100. A packet transmitted from the host 100 to the host interface 211 may include a command or data to be programmed to the NVM 220, and a packet transmitted from the host interface 211 to the host 100 may include a response to the command or data read from the NVM 220. The memory interface 212 may transmit, to the NVM 220, data to be programmed to the NVM 220 or may receive data read from the NVM 220. The memory interface 212 may be implemented to comply with a standard protocol such as Toggle or Open NAND Flash Interface (ONFI).

The FTL 214 may perform various functions such as address mapping, wear-leveling, and garbage collection. The address mapping is an operation for translating a logical address received from the host 100 into a physical address used to actually store data in the NVM 220. The wear-leveling is a technique for preventing excessive degradation of a particular block by allowing blocks in the NVM 220 to be uniformly used and may be, for example, implemented through firmware technology for balancing erase counts of physical blocks. The garbage collection is a technique for securing usable capacity in the NVM 220 by copying valid data of an old block to a new block and then erasing the old block.

The packet manager 215 may generate packets according to a protocol of an interface negotiated with the host 100 or may parse a variety of information from packets received from the host 100. Also, the buffer memory 216 may temporarily store data to be programmed to the NVM 220 or data read from the NVM 220. The buffer memory 216 may be a component provided in the storage controller 210 but may also be provided outside the storage controller 210.

The ECC engine 217 may detect and correct an error on read data read from the NVM 220. In detail, the ECC engine 217 may generate parity bits regarding write data to be written to the NVM 220, and such parity bits may be stored in the NVM 220 together with the write data. When data is read from the NVM 220, the ECC engine 217 may correct an error of read data using parity bits read from the NVM 220 together with the read data and output error-corrected read data.

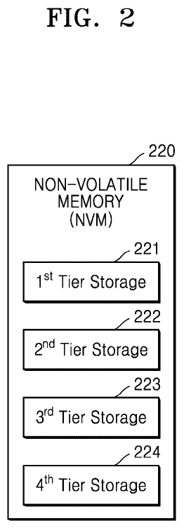

The COM 218 may dynamically adjust the compression method for data depending on the semantics of the data or the tier of storage to which the data will be written. The COM 218 according to an embodiment may perform semantic compression or non-semantic compression on data depending on at least one of the importance of the data, the semantic entropy of the data, and the tier of storage in which the data is to be recorded. Hereinafter, various embodiments of the inventive concept for dynamically adjusting a compression method for data will be described with reference to FIGS. 2 to 8. The COM 218 may be implemented as hardware, software, firmware, or a combination thereof. When the COM 218 is implemented as hardware such as a logic circuit, the hardware configurations of the COM 218 may be implemented within the storage controller 210. When the COM 218 is implemented as software or firmware, instructions of the software or firmware may be executed by the CPU 213.

The NVM 220 may include one or more storages to which tiers are assigned. Tiers may be assigned based on how data to be written to storages is compressed. For example, a first tier may be assigned to a storage where semantically compressed data will be written, a second tier may be assigned to a storage where non-semantically compressed data will be written, and a third tier may be assigned to a storage where uncompressed data will be written. Hereinafter, various embodiments of the inventive concept for dynamically adjusting a method of compressing data to be recorded in storages according to tiers will be described with reference to FIGS. 2 to 8.

FIG. 2 is a block diagram illustrating an NVM of a storage device according to an embodiment.

Referring to FIG. 2, the NVM 220 may include a plurality of storages. The plurality of storages may include one or more storages to which tiers are assigned. The type of data to be stored in a storage may be based on the tier of the storage. The type of data to be stored in a storage to which a tier is assigned may include one type or a plurality of types. In other words, different types of data may be stored in storages to which different tiers are assigned, or the same type of data may be stored in storages assigned to different tiers.

According to an embodiment, a first tier storage 221 may store data of a first type, a second tier storage 222 may store data of a second type, and a third tier storage 223 may store data of a third type. Data of the first type may be semantically compressed data, data of the second type may be non-semantically compressed data, and data of the third type may be uncompressed data.

According to an embodiment, the first tier storage 221 may store first data of the first type and second data of the second type, the second tier storage 222 may store data of the second type, the third tier storage 223 may store data of the third type, and a fourth tier storage 224 may store data of the first type. The first data of the first type may be semantically compressed data, and the second data of the second type may be non-semantically compressed data, which is the remaining first data that is not semantically compressed.

According to an embodiment, the first tier storage 221 may store at least one of first data of the first type, second data of the second type, and third data of the third type. The first data of the first type may be semantically compressed data, the second data of the second type may be non-semantically compressed data, which is the remaining first data that is not semantically compressed, and the third data of the third type may be uncompressed data, which is additional data used for semantic compression of the first data.

According to an embodiment, the first tier storage 221 may store data of the first type and data of the second type. The data of the first type may be semantically compressed data, and the data of the second type may be non-semantically compressed data, which is additional data used for semantic compression of semantically compressed data.

The plurality of storages may be physically different memories. For example, the plurality of storages may be memories with different processing speeds from one another. For example, one or more of the first tier storage 221 to the fourth tier storage 224 may be memories having a fast processing speed, and the other storages may be memories having a relatively slow processing speed.

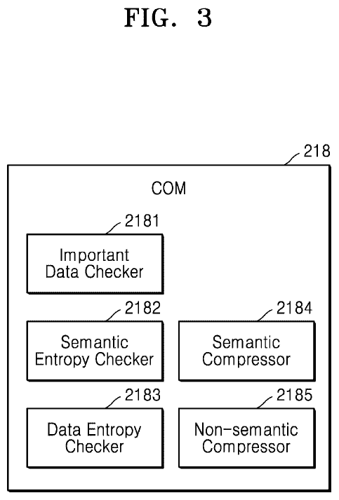

FIG. 3 is a block diagram illustrating a COM constituting a storage controller of a storage device according to an embodiment.

Referring to FIGS. 2 and 3, the COM 218 of the storage device 200 (FIG. 1) may include an important data checker 2181, a semantic entropy checker 2182, a data entropy checker 2183, a semantic compressor 2184, and a non-semantic COM 2185. The important data checker 2181, the semantic entropy checker 2182, and the data entropy checker 2183 may be provided within the COM 218 or may be arranged as components of a storage controller 210 (FIG. 1) outside the COM 218. Alternatively, at least one of the important data checker 2181 and the semantic entropy checker 2182 may be provided within the semantic compressor 2184, and the data entropy checker 2183 may be provided within the non-semantic compressor 2185.

The important data checker 2181, the semantic entropy checker 2182, the data entropy checker 2183, the semantic compressor 2184, and the non-semantic compressor 2185 may each be implemented as hardware, software, firmware, or any combination thereof. When any one of the important data checker 2181, the semantic entropy checker 2182, the data entropy checker 2183, the semantic compressor 2184, and the non-semantic compressor 2185 is implemented as hardware such as a logic circuit, it may be implemented within the storage controller 210. When any one of the important data checker 2181, the semantic entropy checker 2182, the data entropy checker 2183, the semantic compressor 2184, and the non-semantic compressor 2185 is implemented as software or firmware, instructions of the software or firmware may be executed by the CPU 213.

The important data checker 2181 may check whether data input from the host 100 (FIG. 1) is important data.

According to an embodiment, the important data checker 2181 may check a data tag of data and classify the data as important data when the data tag includes tag information indicating a first tier. A data tag may include tag information provided by the host 100 (FIG. 1) to manage data. Here, the tag information may be information that indicates the tier of a storage where data is to be stored. According to an embodiment, the COM 218 may dynamically adjust a method of compressing data depending on the tier of a storage where the data is to be stored.

According to another embodiment, the important data checker 2181 may divide data into a plurality of segments, set the importance of each segment based on semantic information, and classify at least one segment with a pre-set importance as important data.

Semantic information may refer to information that may be preserved by semantic compression. The semantic information may be determined in advance and may include at least one of interest information and type information of a machine learning model. The interest information may be a region of interest in image data, interest information in text data, etc., and the type information of a machine learning model may be information indicating a type according to a learning target of the machine learning model.

The importance of each segment may be set based on whether each segment corresponds to semantic information. For example, the important data checker 2181 may set the importance of a first segment including a region of interest to a first importance and classify the first segment set to the first importance as important data. According to another embodiment, the COM 218 may semantically and losslessly compress data to be stored in upper-tier storages.

The important data checker 2181 may store data not corresponding to important data in the third tier storage 223, but the inventive concept is not limited thereto.

The semantic entropy checker 2182 may compare the semantic entropy of data corresponding to important data with a first threshold value. A semantic entropy may represent the semantic uncertainty of data. The first threshold value may be pre-set depending on the value at which semantic compression is to be performed.

The data entropy checker 2183 may compare the data entropy of data exceeding the first threshold value or data not corresponding to important data with a second threshold value. A data entropy is a measure distinct from the semantic entropy and may indicate the degree of disorder in data. The second threshold may be determined in advance depending on the value at which non-semantic compression is to be performed.

The data entropy checker 2183 may store data having a data entropy exceeding the second threshold value in at least one of the first tier storage 221 and the third tier storage 223. Here, the data exceeding the second threshold may be uncompressed data.

The data entropy checker 2183 may extract remaining data that is not semantically compressed by the semantic compressor 2184 and compare the data entropy of the remaining data with the second threshold value.

The semantic compressor 2184 may perform semantic compression on data having a semantic entropy that is lower than the first threshold value and store semantically compressed data in the first tier storage 221. The semantic compressor 2184 may perform semantic compression for separating and compressing semantic sections of data. Also, the semantic compressor 2184 may further store additional data used for semantic compression of semantically compressed data in the first tier storage 221. The additional data may include, for example, tag information indicating the first tier, type information of a machine learning model, etc. The additional data may be, but is not limited to, data that is non-semantically compressed by the non-semantic compressor 2185 or uncompressed data. The semantic compressor 2184 may map semantically compressed data and additional data and store them in the first tier storage 221. The semantic compressor 2184 according to an embodiment may perform semantic compression only on data corresponding to important data.

The non-semantic compressor 2185 may perform non-semantic compression on data having a data entropy that is lower than or equal to the second threshold value, and store non-semantic compressed data in at least one of the first tier storage 221 and the second tier storage 222. The non-semantic compressor 2185 may perform a general form of compression that removes redundancy in data or finds a pattern to compress data. The semantic compressor 2184 according to an embodiment may determine whether to perform compression before the non-semantic compressor 2185.

According to embodiments, a first tier storage storing semantically and losslessly compressed data may be utilized as an artificial intelligence (AI) storage, thereby enabling faster and more efficient AI algorithms to be performed.

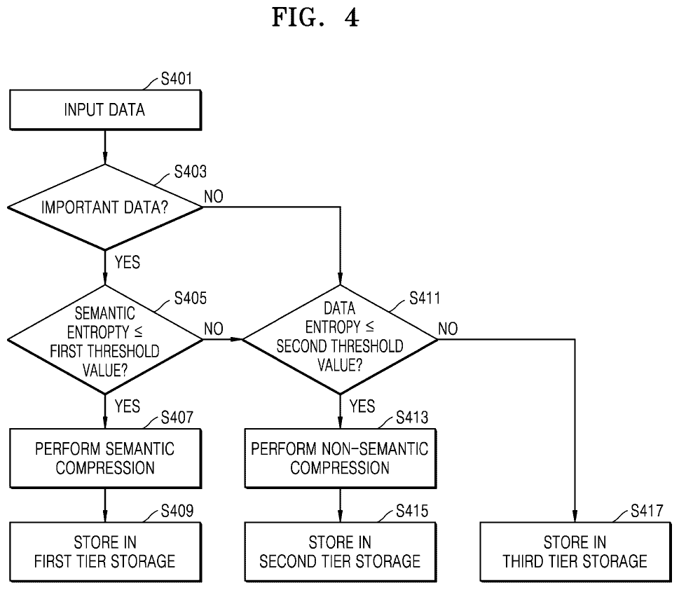

FIG. 4 is a flowchart of a method of operating a storage device, according to an embodiment.

Referring to FIG. 4, when data is input from the host 100 (FIG. 1) (operation S401), the important data checker 2181 checks whether input data is important data (operation S403). The important data checker 2181 may transfer data corresponding to important data (e.g., data deemed important) to the semantic entropy checker 2182 and transfer data not corresponding to important data (e.g., data deemed unimportant) to the data entropy checker 2183.

Next, the semantic entropy checker 2182 compares the semantic entropy of data corresponding to important data with a first threshold value (operation S405). The semantic entropy checker 2182 may transfer data having a semantic entropy that is lower than or equal to a first threshold value to the semantic compressor 2184 and transfer data having a semantic entropy exceeding the first threshold value to the data entropy checker 2183.

Next, the semantic compressor 2184 may perform semantic compression on data having a semantic entropy that is lower than the first threshold value (operation S407) and store semantically compressed data in the first tier storage 221 (operation S409). The semantic compressor 2184 may map semantically compressed data and additional data used for semantic compression and store them in the first tier storage 221. The semantic compressor 2184 may map semantically compressed data and semantic entropy of semantically compressed data and store them in the first tier storage 221. As a result, important data with low semantic uncertainty may be stored in a semantically compressed form in the first tier storage 221.

In addition, the data entropy checker 2183 compares the data entropy of data not corresponding to important data or data of which semantic entropy exceeds the first threshold value with the second threshold value (operation S411), and stores data having a data entropy exceeding the second threshold value in the third tier storage 223 (operation S417). As a result, at least one of unimportant data with a high degree of data disorder and important data with a high degree of semantic uncertainty and a high degree of data disorder may be stored in an uncompressed form in the third tier storage 223. The data entropy checker 2183 may transfer data having a data entropy below the second threshold value to the non-semantic compressor 2185.

Next, the non-semantic compressor 2185 performs non-semantic compression on data having a data entropy below the second threshold value (operation S413) and stores non-semantic compressed data in the second tier storage 222 (operation S415). The non-semantic compressor 2185 may map non-semantically compressed data and the data entropy of the non-semantically compressed data and store them in the second tier storage 222. As a result, at least one of unimportant data with a low degree of data disorder and important data with a high degree of semantic uncertainty and a low degree of data disorder may be stored in a non-semantically compressed form in the second tier storage 222.

In various embodiments, the tier of a storage to store data is determined according to the type of data, but the inventive concept is not limited thereto.

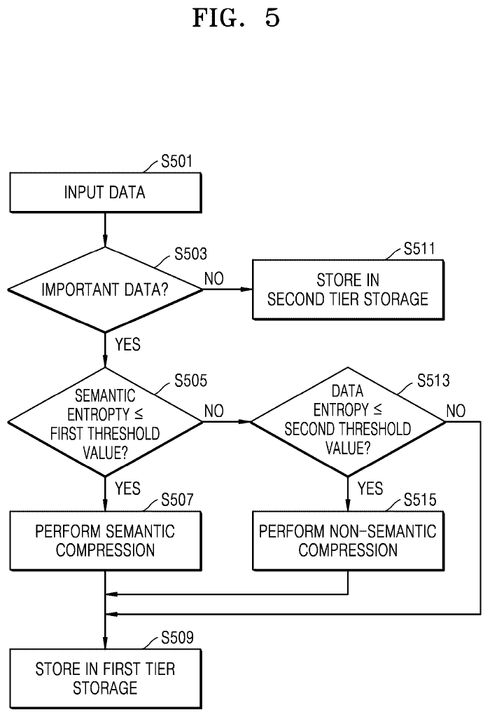

FIG. 5 is a flowchart of a method of operating a storage device, according to an embodiment.

Referring to FIG. 5, when data is input from the host 100 (FIG. 1) (operation S501), the important data checker 2181 checks whether input data is important data (operation S503). The important data checker 2181 may transfer data corresponding to important data to the semantic entropy checker 2182.

Next, the semantic entropy checker 2182 compares the semantic entropy of data corresponding to important data with a first threshold value (operation S505). The semantic entropy checker 2182 may transfer data having a semantic entropy that is lower than or equal to a first threshold value to the semantic compressor 2184 and transfer data having a semantic entropy exceeding the first threshold value to the data entropy checker 2183.

Next, the semantic compressor 2184 may perform semantic compression on data having a semantic entropy that is lower than the first threshold value (operation S507) and store semantically compressed data in the first tier storage 221 (operation S509). The semantic compressor 2184 may map semantically compressed data and additional data used for semantic compression and store them in the first tier storage 221.

In addition, the data entropy checker 2183 compares the data entropy of data not corresponding to important data or data of which semantic entropy exceeds the first threshold value with the second threshold value (operation S513).

Next, the non-semantic compressor 2185 performs non-semantic compression on data having a data entropy below the second threshold value (operation S515) and stores non-semantic compressed data in the first tier storage 221 (operation S509).

In addition, the non-semantic compressor 2185 stores data having data entropy exceeding the second threshold value in the first tier storage 221 (operation S509).

As a result, in the first tier storage 221, important data with low semantic uncertainty may be stored in a semantically compressed form, important data with high semantic uncertainty but low data disorder may be stored in a non-semantically compressed form, or important data with high semantic uncertainty and high data disorder may be stored in an uncompressed form.

When the important data checker 2181 determines that input data is not important data, the important data checker 2181 stores unimportant data in the second tier storage 222 (operation S511).

According to an embodiment, data corresponding to important data and data not corresponding to important data may be stored in storages to which different tiers are assigned.

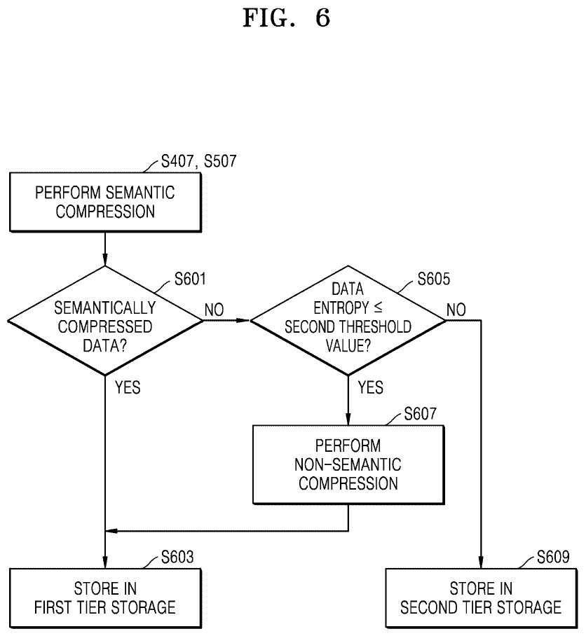

FIG. 6 is a flowchart of a method of operating a storage device, according to an embodiment. Hereinafter, another embodiment of operations after operation S407 of FIG. 4 and operation S507 of FIG. 5 is described with reference to FIG. 6, and descriptions identical to those given above are omitted or briefly given.

Referring to FIG. 6, the semantic compressor 2184 performs semantic compression on data corresponding to important data and having a semantic entropy that is lower than the first threshold value (operation S407 of FIG. 4 or operation S507 of FIG. 5). When data is semantically compressed data generated through semantic compression (operation S601), the semantic compressor 2184 stores the data in the first tier storage 221 (operation S603).

When data corresponds to remaining data that is not semantically compressed (operation S601), the semantic compressor 2184 may transfer the remaining data to the data entropy checker 2183, and the data entropy checker 2183 compares data entropy of the remaining data with the second threshold value (operation S605). The data entropy checker 2183 may transfer remaining data having a data entropy below the second threshold value to the non-semantic compressor 2185.

Next, the non-semantic compressor 2185 performs non-semantic compression on the remaining data having a data entropy below the second threshold value (operation S607) and stores non-semantic compressed remaining data in the first tier storage 221 (operation S603). As a result, the first tier storage 221 may store pre-compressed data in a semantically compressed form and a non-semantically compressed form, that is, in a double-compressed form.

According to an embodiment, remaining semantically uncompressed data may be non-semantically compressed and stored, thereby minimizing data loss due to compression.

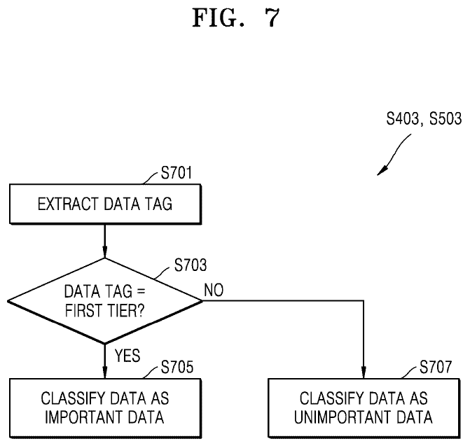

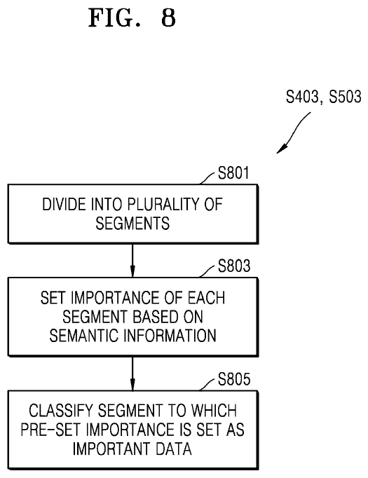

Hereinafter, embodiments of operation S403 of FIG. 4 and operation S503 of FIG. 5 are described with reference to FIGS. 7 and 8, respectively.

FIG. 7 is a flowchart of a method of determining important data, according to an embodiment.

Referring to FIG. 7, the important data checker 2181 extracts a data tag of data input from the host 100 (FIG. 1) (operation S701) and checks whether the data tag includes tag information indicating the first tier (operation S703). Here, the first tier may be an example of information indicating the first tier storage 221, and, when the information indicates a tier of a storage where semantically compressed data is to be written, the information may correspond to the first tier.

When a data tag includes tag information indicating the first tier, the important data checker 2181 classifies corresponding data as important data (operation S705).

When a data tag does not include tag information indicating the first tier, the important data checker 2181 classifies corresponding data as unimportant data (operation S707). Operation S707 assumes the case where a storage in which semantically compressed data is to be written is limited to the first tier storage 221.

FIG. 8 is a flowchart of a method of determining important data, according to an embodiment.

Referring to FIG. 8, the important data checker 2181 divides data into a plurality of segments (operation S801). The plurality of segments may be, but are not limited to, a plurality of segment regions of image data, a plurality of segment words, a plurality of segment sentences of text data, or any combination thereof.

The important data checker 2181 sets the importance of each segment based on semantic information (operation S803). The semantic information may be, for example, information regarding a certain pixel row interval of image data, information regarding a certain moving object of image data, information regarding a phone number of text data, information identifying a first machine learning model that learns a certain moving object in an image, or information identifying a second machine learning model that learns a phone number in text. For example, when the semantic information is phone number information of text data, the important data checker 2181 may set the importance of a segment including a series of numbers indicating a phone number, a series of characters in a first language, a series of characters in a second language, or a series of symbols to a first importance. Here, the important data checker 2181 may set the importance of a segment that does not contain a series of texts indicating a phone number to a second importance.

Next, the important data checker 2181 classifies one or more segments with a pre-set importance level as important data (operation S805). For example, the important data checker 2181 may classify one or more segments having the first importance as important data.

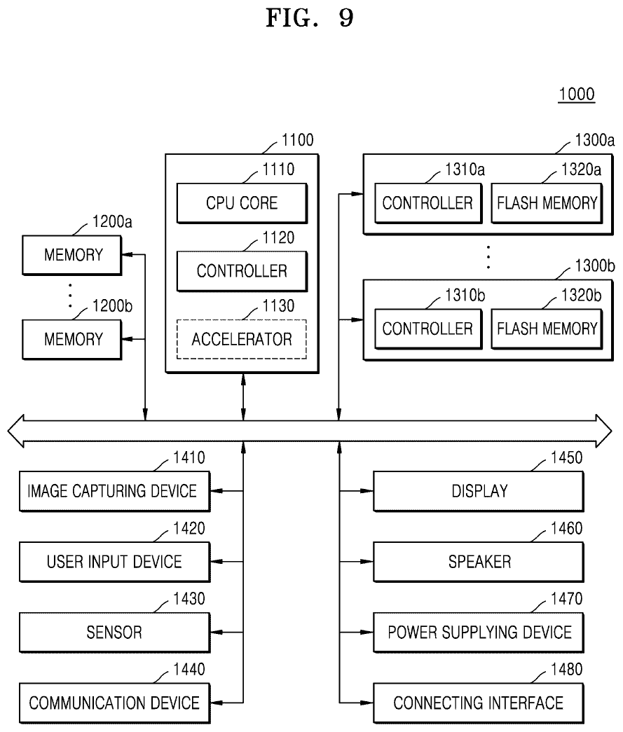

FIG. 9 is a diagram showing a system to which a storage device according to an embodiment is applied. A system 1000 of FIG. 9 may be a mobile system such as a mobile phone, a smartphone, a tablet personal computer (PC), a wearable device, a healthcare device, or an Internet of Things (IoT) device. However, the system 1000 of FIG. 9 is not necessarily limited to a mobile system and may include a PC, a laptop computer, a server, a media player, or an automobile device such as a navigation device.

Referring to FIG. 9, the system 1000 may include a main processor 1100, memories 1200a and 1200b, and storage devices 1300a and 1300b and may additionally include at least one of an image capturing device 1410, a user input device 1420, a sensor 1430, a communication device 1440, a display 1450, a speaker 1460, a power supplying device 1470, and a connecting interface 1480.

The main processor 1100 may control the overall operation of the system 1000, and more particularly, the operations of other components constituting the system 1000. The main processor 1100 may be implemented by a general-purpose processor, a dedicated processor, or an application processor. According to an embodiment, the main processor 1100 may be the host 100 described with reference to FIG. 1.

The main processor 1100 may include one or more CPU cores 1110 and may further include a controller 1120 for controlling the memories 1200a and 1200b and/or the storage devices 1300a and 1300b. According to embodiments, the main processor 1100 may further include an accelerator block 1130, which is a dedicated circuit for high-speed data operation such as AI data operation. The accelerator block 1130 may include a graphics processing unit (GPU), a neural processing unit (NPU), and/or a data processing unit (DPU) and may also be implemented as a separate chip physically independent from the other components of the main processor 1100.

The memories 1200a and 1200b may be used as the main memory device of the system 1000 and may include volatile memories such as SRAMs and/or DRAMs. However, the inventive concept is not limited thereto, and the memories 1200a and 1200b may also include non-volatile memories such as flash memories, PRAMs, and/or RRAMs. The memories 1200a and 1200b may be implemented in the same package as the main processor 1100.

The storage devices 1300a and 1300b may function as non-volatile storage devices that store data regardless of whether power is supplied thereto, and may have a relatively large storage capacity compared to the memories 1200a and 1200b. The storage devices 1300a and 1300b may respectively include storage controllers 1310a and 1310b and non-volatile memories (NVM) 1320a and 1320b that store data under control by the storage controllers 1310a and 1310b. The NVMs 1320a and 1320b may include a V-NAND flash memory having a 2-dimensional (2D) structure or a 3-dimensional (3D) structure but may also include other types of non-volatile memories such as PRAM and/or RRAM. According to embodiment, the storage devices 1300a and 1300b may include the storage device 200 described with reference to FIG. 1, the storage controllers 1310a and 1310b may include the storage controller 210 described with reference to FIG. 1, and the NVMs 1320a and 1320b may include the NVM 220 described with reference to FIG. 1.

According to an embodiment, the storage devices 1300a and 1300b may include one or more storages to which a tier is assigned, and semantically compressed data may be stored in the one or more storages to which the tier is assigned by the storage controllers 1310a and 1310b. One or more storages of the storage devices 1300a and 1300b to which a tier is assigned may be utilized as AI storages of the accelerator block 1130.

The storage devices 1300a and 1300b may be included in the system 1000 but physically separated from the main processor 1100 or may be implemented in the same package as the main processor 1100. Also, the storage devices 1300a and 1300b may be solid state devices (SSDs) or memory cards, and thus the storage devices 1300a and 1300b may be detachably attached to the other components of the system 1000 through an interface such as the connecting interface 1480 to be described below. The storage devices 1300a and 1300b may be devices to which standard protocols such as (UFS, eMMC, or NVMe are applied, but are not necessarily limited thereto.

The image capturing device 1410 may capture a still image or a moving picture and may include a camera, a camcorder, and/or a webcam.

The user input device 1420 may receive various types of data input from a user of the system 1000 and may include a touch pad, a keypad, a keyboard, a mouse, and/or a microphone.

The sensor 1430 may sense various types of physical quantities that may be obtained from outside the system 1000 and transform sensed physical quantities into electrical signals. The sensor 1430 may include a temperature sensor, a pressure sensor, an illuminance sensor, a positional sensor, an acceleration sensor, a biosensor, and/or a gyroscope.

The communication device 1440 may transmit and receive signals to and from other devices outside the system 1000 according to various communication protocols. The communication device 1440 may include an antenna, a transceiver, and/or a modem.

The display 1450 and the speaker 1460 may function as output devices that output visual and auditory information to a user of the system 1000, respectively. The power supplying device 1470 may appropriately convert power supplied from a battery (not shown) embedded in the system 1000 and/or power supplied from an external power source and supply converted power to the components of the system 1000.

The connecting interface 1480 may provide a connection between the system 1000 and an external device, which is capable of being connected to the system 1000 and exchanging data with the system 1000. The connecting interface 1480 may be implemented as one of various interface protocols such as advanced technology attachment (ATA), serial ATA (ATA), external SATA (e-SATA) , small computer small interface (SCSI) , serial attached SCSI (SAS), peripheral component interconnection (PCI), PCI express (PCIe), NVMe, IEEE 1394, universal serial bus (USB), a secure digital (SD) card, a multi-media card (MMC), an eMMC, UFS, an embedded universal flash storage (eUFS), and a compact flash (CF) card interface.

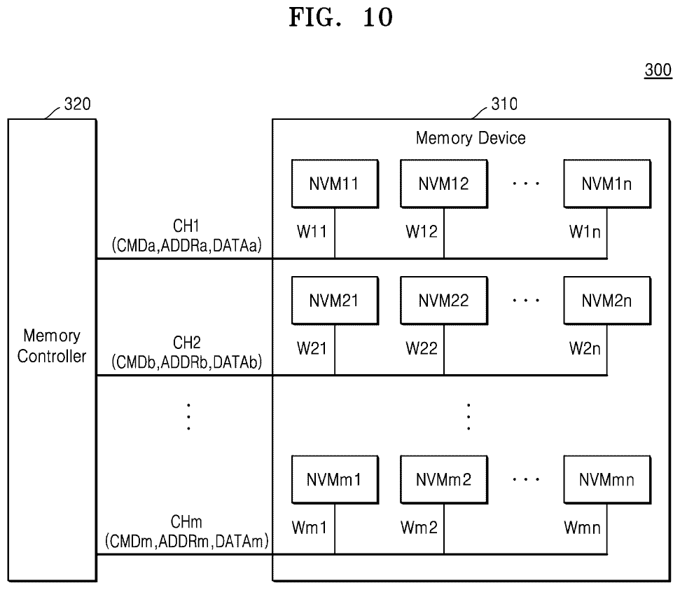

FIG. 10 is a block diagram showing a memory system according to an embodiment.

Referring to FIG. 10, a memory system 300 may include a memory device 310 and a memory controller 320. The memory system 300 may support a plurality of channels CH1 to CHm, and the memory device 310 and the memory controller 320 may be connected to each other through the plurality of channels CH1 to CHm. For example, the memory system 300 may be implemented as a storage device such as an SSD. According to an embodiment, the memory device 310 may include the storage device 200 described with reference to FIG. 1, and the memory controller 320 may include the storage controller 210 described with reference to FIG. 1.

The memory device 310 may include a plurality of NVM devices NVM11 to NVMmn. The NVM devices NVM11 to NVMmn may each be connected to one of the plurality of channels CH1 to CHm through a corresponding way. For example, NVM devices NVM11 to NVM1n may be connected to a first channel CH1 through ways W11 to W1n, and NVM devices NVM21 to NVM2n may be connected to a second channel CH2 through ways W21 to W2n. According to an embodiment, the NVM devices NVM11 to NVMmn may each be implemented as an arbitrary memory unit capable of operating according to an individual command from the memory controller 320. For example, the NVM devices NVM11 to NVMmn may each be implemented as a chip or a die, but the inventive concept is not limited thereto. According to an embodiment, the NVM devices NVM11 to NVMmn may each include at least one of the first tier storage 221 to the fourth tier storage 224 described with reference to FIG. 2. According to an embodiment, the NVM devices NVM11 to NVMmn may each be at least one of the first tier storage 221 to the fourth tier storage 224 described with reference to FIG. 2.

The memory controller 320 may transmit and receive signals to and from the memory device 310 through the channels CH1 to CHm. For example, the memory controller 320 may transmit commands CMDa to CMDm, addresses ADDRa to ADDRm, and data DATAa to DATAm to the memory device 310 or receive data DATAa to DATAm from the memory device 310, through the channels CH1 to CHm.

Through a corresponding channel, the memory controller 320 may select one from among NVM devices connected to the corresponding channel and transmit and receive signals with a selected NVM device. For example, the memory controller 320 may select an NVM device NVM11 from among NVM devices NVM11 to NVM1n connected to the first channel CH1. The memory controller 320 may transmit a command CMDa, an address ADDRa, and data DATAa to the selected NVM device NVM11 or receive the data DATAa from the selected NVM device NVM11, through the first channel CH1.

The memory controller 320 may transmit and receive signals to and from the memory device 310 in parallel through different channels. For example, the memory controller 320 may transmit a command CMDb to the memory device 310 through the second channel CH2 while the command CMDa is being transmitted to the memory device 310 through the first channel CH1. For example, the memory controller 320 may receive data DATAb from the memory device 310 through the second channel CH2 while the data DATAa is being received from the memory device 310 through the first channel CH1.

The memory controller 320 may control the overall operation of the memory device 310. The memory controller 320 may control each of the NVM devices NVM11 to NVMmn connected to the channels CH1 to CHm by transmitting signals through the channels CH1 to CHm. For example, the memory controller 320 may control one selected from among the NVM devices NVM11 to NVM1n by transmitting the command CMDa and the address ADDRa to the first channel CH1.

The NVM devices NVM11 to NVMmn may each operate under the control by the memory controller 320. For example, the NVM device NVM11 may be programmed with the data DATAa according to the command CMDa, the address ADDRa, and the data DATAa provided through the first channel CH1. For example, an NVM device NVM21 may read the data DATAb according to the command CMDb and the address ADDRb provided to the second channel CH2 and transmit the read data DATAb to the memory controller 320.

Although FIG. 10 shows that the memory device 310 communicates with the memory controller 320 through m channels and the memory device 11 includes n NVM devices in correspondence to each channel, the number of channels and the number of NVM devices connected to one channel may vary.

A storage device according to the inventive concept may optimize storage space and access and response speed to the storage space by dynamically adjusting semantic compression and general compression for data according to tiers of storages in which data is to be stored.

Also, the storage device according to the inventive concept may minimize semantic data loss by semantically compressing data to be stored in an upper-tier storage.

Also, since the storage device according to the inventive concept may store data through general compression without discarding remaining data that is not semantically compressed, overall data loss may be minimized.

While the inventive concept has been particularly shown and described with reference to embodiments thereof, it will be understood that various changes in form and details may be made therein without departing from the spirit and scope of the following claims.

What is claimed is:

1. A storage device comprising:
a storage controller; and
a non-volatile memory,
wherein the storage controller comprises:
an important data checker configured to check whether input data is important data;
a semantic entropy checker configured to compare a semantic entropy of the input data with a first threshold value when the input data is deemed important; and
a semantic compressor configured to, when a semantic entropy of the input data is less than or equal to the first threshold value, perform semantic compression on the input data, and store semantically compressed data in a first tier storage of the non-volatile memory.

2. The storage device of claim 1, wherein the semantic compressor is configured to further store additional data used for semantic compression of the input data in the first tier storage.

3. The storage device of claim 1, further comprising:
a data entropy checker configured to compare a data entropy of the input data with a second threshold value when the semantic entropy of the input data exceeds the first threshold value; and
a non-semantic compressor configured to, when a data entropy of the input data is less than or equal to the second threshold value, perform non-semantic compression on the input data, and store non-semantically compressed data in a second tier storage of the non-volatile memory.

4. The storage device of claim 1, further comprising:
a data entropy checker configured to compare a data entropy of the input data with a second threshold value when the input data is deemed unimportant; and
a non-semantic compressor configured to, when a data entropy of the input data is less than or equal to the second threshold value, perform non-semantic compression on the input data, and store non-semantically compressed data in a second tier storage of the non-volatile memory.

5. The storage device of claim 3, wherein the data entropy checker stores the input data in a third tier storage of the non-volatile memory when the data entropy of the input data exceeds the second threshold value.

6. The storage device of claim 1, wherein the important data checker stores the input data in a second tier storage of the non-volatile memory when the input data is deemed unimportant.

7. The storage device of claim 1, further comprising:
a data entropy checker configured to compare a data entropy of the input data with a second threshold value when the semantic entropy of the input data exceeds the first threshold value; and
a non-semantic compressor configured to, when a data entropy of the input data is less than or equal to the second threshold value, perform non-semantic compression on the input data, and store non-semantically compressed data in the first tier storage.

8. The storage device of claim 7, wherein the data entropy checker stores the input data in the first tier storage when the data entropy of the input data exceeds the second threshold value.

9. The storage device of claim 1, wherein the important data checker checks a data tag of the input data and classifies the input data as important data when the data tag comprises tag information indicating a first tier.

10. The storage device of claim 1, wherein the important data checker divides the input data into a plurality of segments, sets importance of each segment based on semantic information, and classifies at least one segment with a pre-set importance as important data.

11. The storage device of claim 10, wherein the semantic information comprises at least one of interest information and type information of a machine learning model.

12. The storage device of claim 1, further comprising:
a data entropy checker configured to extract remaining data not semantically compressed by the semantic compressor and compare a data entropy of the remaining data with a second threshold value; and
a non-semantic compressor configured to, when a data entropy of the remaining data is less than or equal to the second threshold value, perform non-semantic compression on the remaining data, and store non-semantically compressed data in the first tier storage.

13. A storage device comprising a storage controller and a non-volatile memory, wherein the storage controller comprises a semantic compressor and a non-semantic compressor,
the non-volatile memory comprises:
a first tier storage configured to store data of a first type;
a second tier storage configured to store data of a second type; and
a third tier storage configured to store data of a third type, and
the data of the first type comprises data semantically compressed by the semantic compressor, the data of the second type comprises data non-semantically compressed by the non-semantic compressor, and the data of the third type comprises uncompressed data.

14. The storage device of claim 13, wherein the data of the first type comprises data to which tag information indicating a first tier is added by a host or data to which a pre-set importance is set based on semantic information of the data, and
the semantic information comprises at least one of interest information and type information of a machine learning model.

15. The storage device of claim 13, wherein the first tier storage stores first data of the first type,
the first tier storage further stores second data of the second type,
the first data comprises data semantically compressed by the semantic compressor, and
the second data comprises remaining of the first data, which is not semantically compressed by the semantic compressor and non-semantically compressed by the non-semantic compressor.

16. A method of operating a storage device, the method comprising:
checking whether input data is important data;
comparing a semantic entropy of the input data with a first threshold value when the input data is deemed important;
performing semantic compression on the input data when the semantic entropy of the input data is less than or equal to the first threshold value; and
storing semantically compressed data in a first tier storage of a non-volatile memory.

17. The method of claim 16, further comprising:
comparing a data entropy of the input data with a second threshold value when the semantic entropy of the input data exceeds the first threshold value;
performing non-semantic compression on the input data when a data entropy of the input data is less than or equal to the second threshold value; and
storing non-semantically compressed data in a second tier storage of the non-volatile memory.

18. The method of claim 16, further comprising:
comparing a data entropy of the input data with a second threshold value when the input data is deemed unimportant;
performing non-semantic compression on the input data when a data entropy of the input data is less than or equal to the second threshold value; and
storing non-semantically compressed data in a second tier storage of the non-volatile memory.

19. The method of claim 16, further comprising:
comparing a data entropy of the input data with a second threshold value when the semantic entropy of the input data exceeds the first threshold value;
performing non-semantic compression on the input data when a data entropy of the input data is less than or equal to the second threshold value; and
storing non-semantically compressed data in the first tier storage.

20. The method of claim 16, further comprising:
extracting remaining data that is not semantically compressed by a semantic compressor;
comparing a data entropy of the remaining data with a second threshold value;
performing non-semantic compression on the remaining data when a data entropy of the remaining data is less than or equal to the second threshold value; and
storing non-semantically compressed data in the first tier storage.
